(19) United States
(12) Patent Application Publication
(10) Pub. No.: US 2009/0053895 A1
(43) Pub. Date: Feb. 26, 2009

(54) FILM FORMING METHOD OF POROUS FILM AND COMPUTER-READABLE RECORDING MEDIUM

(75) Inventors: Yasuhiro OSHIMA, Austin, TX (US); Shinji Ide, Amagasaki-Shi (JP); Yusaku Kashiwagi, Nirasaki-Shi (JP); Kotaro Miyatani, Nirasaki-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/171,952

(22) Filed: Jul. 11, 2008

Related U.S. Application Data
(63) Continuation of application No. PCT/JP07/50284, filed on Jan. 12, 2007.

(30) Foreign Application Priority Data
Jan. 13, 2006 (JP) 2006-005928

(51) Int. Cl. H01L 21/311

(52) U.S. Cl. 438/692; 257/E21.251

(57) ABSTRACT

There is provided a method for forming a porous dielectric film stably by: forming a surface densification layer by processing a surface of an SiOCH film formed by a plasma CVD process while using an organic silicon compound source; and releasing CHx groups or OH group from the SiOCH film underneath the surface densification layer by hydrogen plasma processing through the surface densification layer with a controlled rate.

### CROSS-REFERENCE TO RELATED APPLICATIONS

The present invention is a continuation-in-part application of PCT/JP2007/050284 field on Jan. 12, 2007 based on Japanese priority application 2006-005928 filed on Jan. 13, 2006, the entire contents of each are incorporated by reference.

### BACKGROUND OF THE INVENTION

The present invention generally relates to forming method of dielectric films and more particularly to a forming method of an SiOCH film.

In recent miniaturized semiconductor devices, there is used so-called multilayer interconnection structure for electrically interconnecting a vast number of semiconductor elements formed on a substrate. In multilayer interconnection structure, a number of interlayer insulation films each embedded with an interconnection pattern are laminated, wherein an interconnection pattern of one layer is connected to an interconnection pattern of an adjacent layer or to a diffusion region in the substrate via a contact hole formed in the interlayer insulation film.

With such miniaturized semiconductor devices, complex interconnection patterns are formed in the interlayer insulation film with close distance, and thus, wiring delay (RC delay) of electric signals caused by parasitic capacitance in the interlayer insulation film becomes a serious problem. Thus, with the interconnection technology of high-speed and low power consumption, reduction of the product of wiring resistance R and wiring capacitance C is becoming a paramount problem.

Thus, with recent ultra-miniaturized semiconductor devices of these days called submicron devices or sub-quarter micron devices, it has been practiced to use a F-doped silicon oxide film (SiOF) film having a specific dielectric constant of 3-3.5 for the interlayer insulation film that constitutes the multilayer interconnection structure, in place of conventional silicon oxide film (SiO₂ film) having a specific dielectric constant of about 4.

However, there is a limitation of decreasing the specific dielectric constant as long as SiOF film is used, and it has been difficult to attain the specific dielectric constant of less than 3.0, which is required in the semiconductor devices of the generation characterized by the design rule of 0.1 μm or later, with such an SiO₂ base insulation film.

While there are various candidate materials for the so-called low dielectric constant (low-K) insulation films having a lower specific dielectric constant, the material used for the interlayer insulation film of multilayer interconnection structure is not only required to have a low specific dielectric constant but also required have a high mechanical strength and good stability against thermal processing.

An SiOCH film is a promising material for the low dielectric constant interlayer insulation film for use in ultra high-speed semiconductor devices of next generation in view of the fact that it has a sufficient mechanical strength and is capable of realizing the specific dielectric constant of 2.5 or less, and further in view of the fact that it can be formed by a CVD process suitable for the manufacturing process of semiconductor devices.

Conventionally, it is reported that an SiOCH film can be formed by using a parallel-plate type plasma processing apparatus. However, an SiOCH film formed by ordinary CVD process has a specific dielectric constant of 3-4, while this value does not reach the specific dielectric constant of about 2.2, which is achieved by the insulation film of coating type such as organic SOG or SiLK (registered trademark).

### SUMMARY OF THE INVENTION

As one possible approach to realize the specific dielectric constant comparable to that of such a coating type insulation film while using the SiOCH film, it is conceivable to form the film in the form of a porous film. For example, Patent Reference 2 describes a technology for obtaining a porous film by exposing the SiOCH film deposited by a CVD process to hydrogen radicals excited by microwave plasma and removing the CHx groups or OH groups from the SiOCH film thus deposited on a substrate.

However, with such an approach of modifying the SiOCH film formed on a substrate by applying thereto the hydrogen plasma processing, it becomes necessary to carry out delicate control during the modifying process, and it has been difficult to carry out the modifying process with reproducibility in mass production line.

More specifically, the hydrogen radicals excited by plasma cause breaking in the Si—CHx bond or Si—OH bond with the aforementioned technology, while the disconnected CHx groups or OH groups are discharged to the outside of the film in the form of methane (CH₄) molecules. In the case the modifying process is conducted under an optimum condition, the methane molecules thus formed function to cause dilatation in the SiOCH film, and there are formed a space or pores in the film. With this, the specific dielectric constant of the SiOCH film is decreased.

However, with such conventional modification process, there tends to occur contraction rather than the dilatation in the SiOCH film in the case the process condition of the modification processing falls outside the optimum range, and there may be caused unwanted increase of specific dielectric constant in the film as a result of increase of density associated with the contraction.
Patent Reference 1 WO2005/045916
Patent Reference 2 Japanese Laid-Open Patent Application 2003-503849
Non-Patent Reference 1 A. Grill and D. A. Neumayer, J. Appl. Phys. vol. 94, No. 10, Nov. 15, 2003

In a first aspect, the present invention provides a film forming method of a porous film, comprising the steps of: forming a dielectric film containing an organic functional group and a hydroxyl group on a substrate by using an organic silicon compound source; forming a surface densification layer on a surface of said dielectric film by applying a densification processing to said surface of said dielectric film, said densification processing removing said organic functional group; exposing said dielectric film formed with said surface densification layer to hydrogen radicals excited by plasma; and forming pores in a main part of said dielectric film by exposing said dielectric film formed with said surface densification layer to hydrogen radicals excited by plasma such that said organic functional group and hydroxyl group are removed.

In another aspect, the present invention provides a computer-readable medium recorded with a program, said program causing a general purpose computer to control a substrate processing system and causing said substrate processing system to carry out a film forming processing of a porous film on a silicon substrate, said substrate processing system coupling a first substrate processing apparatus and a second substrate processing apparatus with each other, said film forming processing comprising a step for introducing a substrate to be processed into said first processing apparatus; forming a dielectric film containing an organic functional group and a hydroxyl group on said substrate in said first substrate processing apparatus by an organic silicon compound source; forming a surface densification layer on a surface of said dielectric film by carrying out a densification processing to said surface of said dielectric film, said densification processing removing said organic functional group; introducing said substrate to be processed applied with said densification processing into said second substrate processing apparatus; and forming pores in a main part of said dielectric film by exposing said dielectric film formed with said surface densification layer to hydrogen radicals excited by plasma such that said organic functional group is removed.

According to the present invention, the organic functional groups generally designated as CHx, such as CH₃, C₂H₅, . . . , or the hydroxyl group (OH) contained in the dielectric film is discharged to the outside of the film with a controlled rate in the pore forming step, by carrying out the film formation of the porous film by the steps of: forming the dielectric film containing an organic functional group and a hydroxyl group on a substrate by an organic silicon compound source; forming a surface densification layer having a higher density than a main part of the dielectric film on a surface of the dielectric film by carrying out a densification processing removing the organic functional group and the hydroxyl group; and forming pores in the main part of the dielectric film by exposing the dielectric film formed with the surface densification layer to the hydrogen radicals excited by plasma such that the organic functional group and the hydroxyl group are removed. Thereby, it becomes possible to suppress the shrinkage of the dielectric film at the time of the pore forming step effectively. As a result, increase of density of the dielectric film is suppressed and it becomes possible to obtain a dielectric film of low dielectric constant.

Further, by shutting off the film forming source gas alone, after the film forming process, while continuing the supply of the plasma gas and the oxidizing gas and further continuing the supply of the plasma power, formation of particles at the end of the film forming process is effectively suppressed, and it becomes possible to improve the yield of film formation significantly.

### BRIEF DESCRIPTION OF THE DRAWINGS

FIG. 1 is a diagram showing the construction of a film forming apparatus used with the present invention;

FIGS. 2A-2C are diagrams showing a film forming method according to a first embodiment of the present invention;

FIG. 3 is a diagram showing the construction of a film forming apparatus used with the present invention for formation of porous film;

FIG. 4 is a diagram showing the construction of a film forming apparatus used with the present invention for forming a porous film;

FIG. 5 is a diagram explaining the effect of the first embodiment of the present invention;

FIG. 6 is a diagram showing the processing conditions of FIGS. 2A-2C and the k-values of the obtained porous films;

FIG. 7 is an FT-IR spectrum of the SiOCH film obtained with the first embodiment of the present invention;

FIG. 8 is a diagram showing the construction of a clustered film forming apparatus used with the first embodiment of the present invention;

FIG. 9 is a flowchart showing the film forming method of the first embodiment of the present invention carried out by using the clustered substrate processing apparatus of FIG. 7;

FIGS. 10A-10D are diagrams showing a film forming method according to a second embodiment of the present invention;

FIG. 11A is a diagram showing the relationship between a processing time and leakage current with the second embodiment of the present invention;

FIG. 11B is a diagram showing the relationship between an O₂/Ar flow rate ratio and leakage current with the second embodiment of the present invention;

FIG. 12A is a diagram showing the change of processing time and leakage current with the second embodiment of the present invention;

FIG. 12B is a diagram showing the relationship between an O₂/H₂ flow rate ratio and leakage current with the second embodiment of the present invention;

FIG. 13 is a table showing the experimental condition used with the second embodiment;

FIG. 14 is another table showing the experimental condition used with the second embodiment;

FIG. 15 is an XPS spectrum of the SiOCH film obtained with the second embodiment of the present invention;

FIG. 16 is a SIMS profile of the SiOCH film obtained with the second embodiment of the present invention;

FIG. 17 is a diagram showing a part of FIG. 16 with enlarged scale;

FIG. 18 is a diagram showing a third embodiment of the present invention;

FIG. 19 is a diagram showing the construction of a clustered film forming apparatus used with the third embodiment of the present invention;

FIG. 20 is a table showing the experimental condition used with the fourth embodiment of the present invention;

FIGS. 21A-21C are diagrams explaining a fourth embodiment of the present invention;

FIGS. 22A-22C are further diagrams explaining the fourth embodiment of the present invention;

FIGS. 23A and 23B are further diagrams explaining the fourth embodiment of the present invention.

### BEST MODE FOR IMPLEMENTING THE INVENTION

### First Embodiment

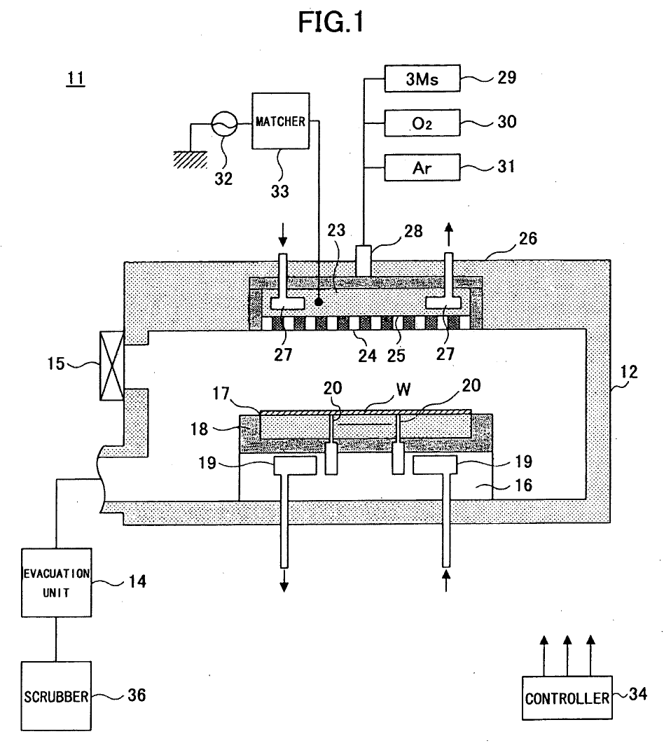

FIG. 1 shows the construction of a parallel-plate type substrate processing apparatus 11 used for the film forming processing of dielectric film with the present invention.

Referring to FIG. 1, the substrate processing apparatus 11 includes a processing vessel 12 formed of a conductive material such as anodized aluminum, wherein the processing vessel 12 is evacuated by an evacuation apparatus 14 such as a turbo molecular pump via an evacuation port 13, and there is provided a susceptor 17 inside the processing vessel 12 in a matter supported by a susceptor support base 16 of generally cylindrical shape. The susceptor 17 holds thereon a substrate W to be processed. The susceptor 17 functions also as the lower electrode of the parallel plate substrate processing apparatus 11, and there is provided an insulator 18 of ceramic or the like between the susceptor support base 16 and the susceptor 17. Further, the processing vessel 12 is grounded.

In the interior of the susceptor base 16, there is provided a coolant flow path 19, wherein the susceptor 17 and the substrate W to be processed thereon are controlled to a desired substrate temperature at the time of the substrate processing by causing to circulate a coolant in the coolant path 19.

Further, there is provided a gate valve 15 on the sidewall of the processing vessel 12, wherein the substrate W to be processed in loaded and unloaded to and from the processing vessel 12 in the state the gate valve 15 is opened.

The evacuation apparatus is further connected to a scrubber 36, and the scrubber 36 neutralizes the emission gas from the processing vessel 12 evacuated by the evacuation apparatus 14. For example, the scrubber 36 may be the apparatus that converts an ambient gas to a harmless substance by causing incineration or thermal decomposition by using a predetermined catalyst.

On the susceptor base 16, there are provided lift pins 20 movable in up and down directions by an elevation mechanism (not shown) for the purpose of handing over the semiconductor substrate W to be processed. Further, the susceptor 17 is formed with a depressed part of circular plate shape on the top surface thereof at the central part, wherein an electrostatic chuck (not shown) of the shape corresponding to the substrate W to be processed is provided on such a circular plate-like depression. Thereby, the substrate W to be processed thus placed on the susceptor 17 is electrostatically attracted to the electrostatic chuck upon application of D.C. voltage.

Further, there is provided a showerhead 23 over the susceptor 17 generally in parallel to the susceptor 17 so as to face the substrate W to be processed on the susceptor 17.

On the surface of the susceptor 17 facing the showerhead 23, there is provided an electrode plate 25 of aluminum, or the like, having a large number of gas supply openings 24, wherein the showerhead 23 is supported on the ceiling part of the processing vessel 12 by an electrode supporting part 26. In the interior of the showerhead 23, there is provided another coolant path 27, and the showerhead 23 is maintained to a desired temperature at the time of the substrate processing by causing a coolant to flow through the coolant path 27.

Further, there is connected a gas inlet tube 28 to the showerhead 23, while the gas inlet tube 28 is connected to a source vessel 29 holding a trimethyl silane ((CH₃)₃SiH) source, an oxidizer gas source 30 holding an oxygen gas and further to an Ar gas source 31 holding an argon (Ar) gas, via respective mass flow controllers and valves.

The source gas and the processing gas from the gas sources 29-31 are mixed in a space (not shown) formed inside the showerhead 23 via the gas inlet tube 28 and are supplied to the processing space in the vicinity of the surface of the substrate W to be processed via the gas supply openings 24 of the showerhead 23.

Further, the showerhead 23 is connected to a second high frequency power source 32 via a second matching box 33, wherein the high-frequency source 32 supplies a high frequency power of the frequency of 450 kHz-300 MHz, preferably in the range of 13.56-150 MHz to the showerhead 23. By supplying such high-frequency power of high frequency, the showerhead 23 functions as the upper electrode and plasma is formed inside the processing vessel 12. For the plasma source, it is also possible to use microwave type source or ICP type source.

Further, the substrate processing apparatus 11 of FIG. 1 has a control part 34 controlling overall operation of the processing vessel 11 including the film forming processing upon the substrate W to be processed. The control part 34 may be formed of a microcomputer control unit equipped with an MPU (micro processing unit), a memory unit, and the like, wherein the control part 34 stores a program for controlling various parts of the apparatus according to a predetermined sequence in the memory unit and controls the foregoing parts of the apparatus according to this program.

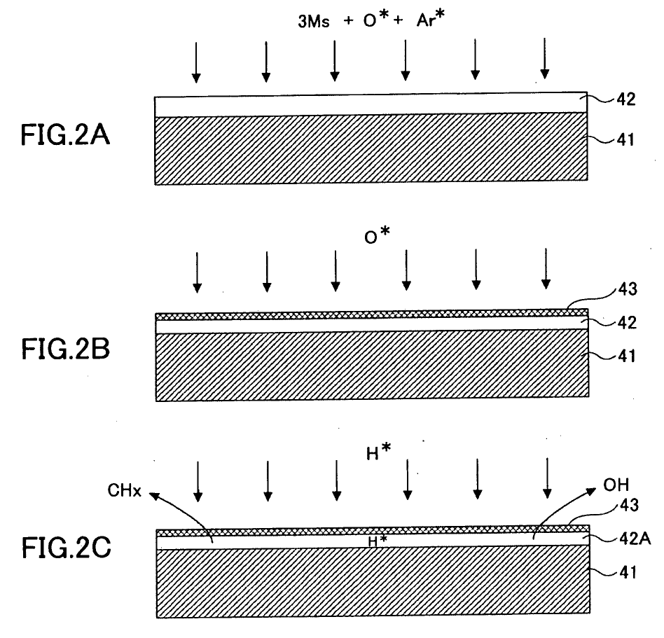

FIGS. 2A-2C show a film forming method according to a first embodiment of the present invention.

Referring to FIG. 2A, a silicon substrate 41 is introduced into the substrate processing apparatus 11 of FIG. 1, and there is formed a so-called SiOCH film 43, which contains Si and oxygen as major constituent elements and further contains carbon and hydrogen, on the surface of the silicon substrate 41 with a deposition rate of 500-2000 nm/minute with a film thickness of 100-1000 nm, preferably 200-400 nm, under the pressure of 13.3-13333 Pa, preferably 100-1000 Pa at the substrate temperature of room temperature −200° C., while supplying an Ar gas with the flow rate of 100-1000 SCCM, preferably 100-600 SCCM, an oxygen gas with the flow rate of 50-2000 SCCM, preferably 50-200 SCCM, and an organic silicon compound gas such as trimethyl silane (3MS) with a flow rate of 50-2000 SCCM, preferably 50-200 SCCM, and by supplying a high frequency power of the frequency of 13-150 MHz to the showerhead 23 from the high frequency power source 32 with the high frequency power of 50-3000 W, preferably 100-750 W.

For example, the film formation of the SiOCH film may be conducted under the pressure of 300 Pa at the substrate temperature of 45° C. by supplying the Ar gas to the processing vessel with the flow rate of 600 SCCM, the oxygen gas with the flow rate of 100 SCCM and the trimethyl silane gas with the flow rate of 100 SCCM, while supplying the high-frequency power of the frequency of 13.56 MHz to the showerhead 23 with the power of 500 W. With this, the SiOCH film can be formed with the thickness of about 400 nm with a film forming rate of 1500 nm/minute. Here, it should be noted that, in the substrate processing apparatus 11, the distance between the showerhead 23 and the susceptor 17 is set to 25 mm. The larger the foregoing distance, the more the plasma damage is reduced, leading to improvement of uniformity. For the distance, it is preferable to use the range of 10-500 nm.

The SiOCH film thus formed has a specific dielectric constant of about 3-4.

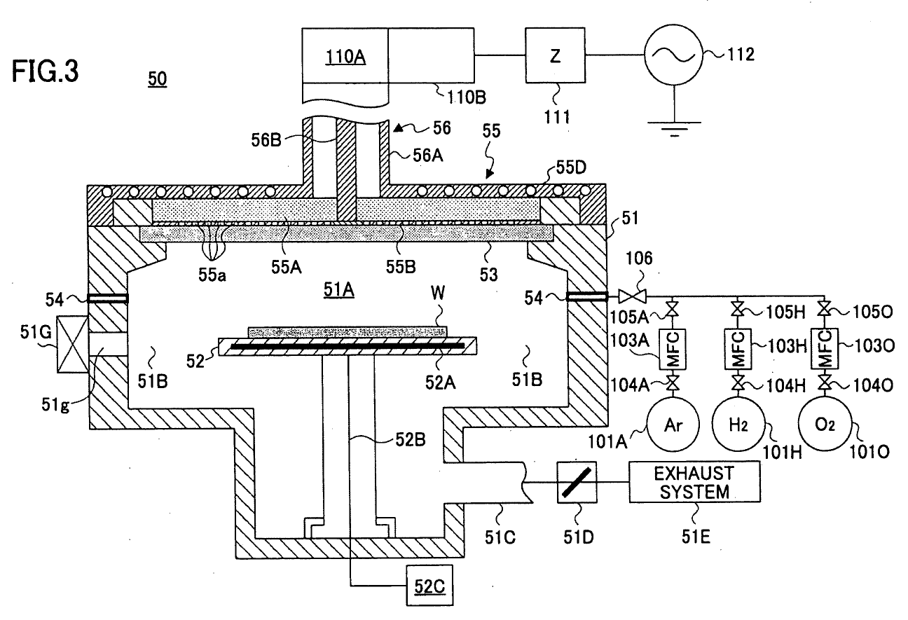

Next, in the step of FIG. 2B, the supply of the trimethyl silane gas to the structure of FIG. 2A is interrupted in the same parallel-plate type processing apparatus 11 while continuing the supply of the Ar gas and the oxygen gas and the high-frequency power, and the surface of the SiOCH film 42 is subjected to plasma processing at the substrate temperature of room temperature to 200° C., preferably the same substrate temperature used at the time of the film formation of the SiOCH film 42. As a result, the CHx groups such as CH₃ or C₂H₅ or OH group on the surface are substituted with oxygen, and thus, there is formed a densification layer 43 of higher oxygen concentration, and hence having a composition closer to SiO₂, at the surface of the SiOCH film 42 with the thickness of 5-20 nm, preferably 10-15 nm as measured from the surface thereof. Here, it should be noted that the modification process of FIG. 2B may be conducted by oxygen radicals formed by plasma. For such plasma processing, surface reflection wave plasma, magnetron plasma, or microwave plasma to be explained with reference to FIG. 3 may be used. By conducting the modification processing of FIG. 2B with the plasma of low energy, damaging to the SiOCH film 42 is reduced. Preferably, the proportion of the densification layer is set to 0.5-20%, particularly 2.5-7.5% of the thickness of the SiOCH film 42.

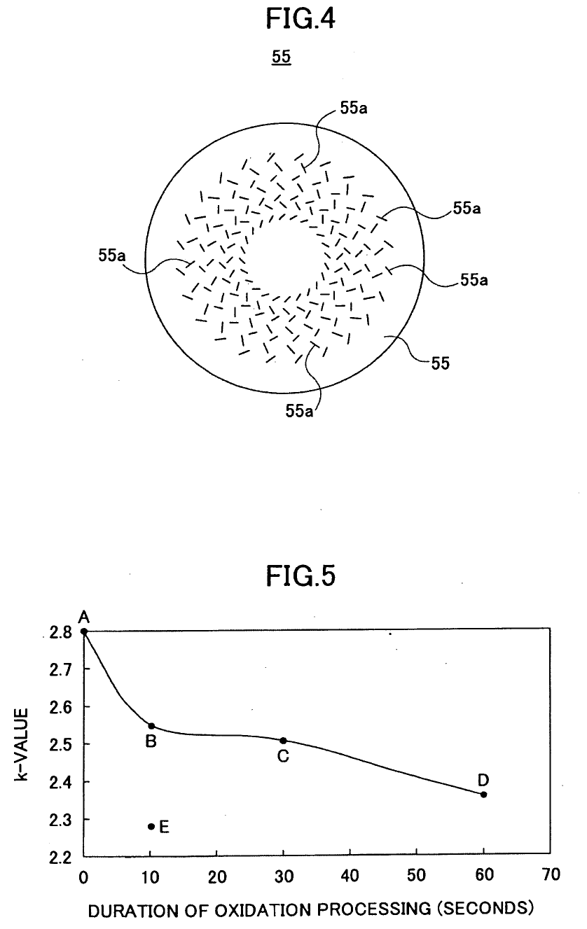

The process of FIG. 2B is conducted for 10-200 seconds, preferably 10-60 seconds. Thereafter, with the present embodiment, the substrate thus formed with the densification layer of FIG. 2B is introduced into the microwave plasma processing apparatus shown in FIGS. 3 and 4 in the step of FIG. 2C, and the SiOCH film underneath the densification layer 43 is subjected to modification by using the hydrogen radicals excited by plasma. With this, pores are formed in the SiOCH film and there is obtained a porous film 42A of SiOCH composition.

Referring to FIG. 3, the plasma processing apparatus includes a processing vessel 51 formed with a processing space 51A and a substrate stage 52 is provided inside the processing space 51A in the processing vessel 51 for holding the substrate W to be processed. The processing vessel 51 is evacuated at an evacuation port 51C by an APC (auto pressure controller) 51D and an evacuation unit 11E via a space 51B formed so as to surround the stage 52.

The stage 52 is provided with a heater 52A, wherein the heater 52A is driven by a power source 52C via a drive line 52B.

Further, the processing vessel 51 is provided with a substrate load/unload opening 51g and a cooperating gate valve 51G, and the substrate W to be processed is loaded and unloaded to and from the processing vessel 11 via the load/unload opening 51g.

On the processing vessel 51, there is provided an opening in correspondence to the substrate W to be processed, wherein the opening is closed by a top plate 53 of dielectric such as quartz glass. Underneath the top plate 53, there is provided a gas ring 54 provided with a gas inlet and a large number of gas ejection openings so as to face the substrate W to be processed.

Here, the top plate 53 functions as a microwave window and there is provided a planar antenna 55 of radial slot line antenna over the top plate 53.

In the illustrate example, a radial line slot antenna is used for the microwave antenna 55, and thus, the antenna 55 includes a planar antenna plate 55B on the top plate 53, and there is disposed a retardation plate 55A of dielectric, such as quartz or the like, so as to cover the planar antenna 55B. Further, there is provided a conductive cover 55D so as to cover the retardation plate 55A. The cover 55D is formed with a cooling jacket for cooling the top plate 53, the planar antenna plate 55B and the retardation plate 55A, wherein thermal damaging is prevented and it becomes possible to form stable plasma.

As shown in FIG. 4, the planar antenna plate 55B is formed with a large number of slots 55a and 55b, wherein a coaxial waveguide 56 formed of an outer conductor 56A and an inner conductor 56B is connected to the central part of the antenna 55. Thereby, the inner conductor 56B penetrates through the retardation plate 55A and is connected and coupled to the central part of the planar antenna 55B.

The coaxial waveguide 56 is connected to the waveguide 110B of rectangular cross-section via a made conversion part 110A, wherein the waveguide 110B is connected to the microwave source 112 via an impedance matching box 111. Thus, the microwave formed in the microwave source 112 is supplied to the planar antenna 55B via the rectangular waveguide 111B and coaxial waveguide 56.

FIG. 4 shows the construction of the radial line slot antenna 55 in detail. It should be noted that FIG. 4 is a front view diagram of the planar antenna plate 55B.

Referring to FIG. 3, it can be seen that the planar antenna plate 55B is formed with a large number of slots 55a concentrically each with a perpendicular orientation to an adjacent slot (T-shaped or ha-shaped form)

Thus, when a microwave is supplied to such a radial line slot antenna 55B from the coaxial waveguide tube 56, the microwave propagates in the antenna 55B while spreading in the radial direction and experiences wavelength compression by the retardation plate 55A. Thus, the microwave is emitted from the slots 55a in the direction generally perpendicular to the planar antenna plate 55B in the form of circular polarization wave.

Further, with the microwave plasma processing apparatus 50, a rare gas source 101A of Ar or the like, a hydrogen gas source 101H, and an oxygen gas source 1010, are connected to the gas ring 54 via respective MFCs 103A, 103H and 1030 and via respective valves 104A, 104H and 104O and further via a common valve 106 as shown in FIG. 3. As explained before, the gas ring 54 is provided with a large number of gas ejection ports so as to surround the stage 52 uniformly, and as a result, the Ar gas and the hydrogen gas are introduced into the processing space 51A in the processing vessel uniformly.

In operation, the processing space 51A inside the processing vessel 51 is evacuated via the evacuation port 51C and is set to a predetermined pressure. Further, in addition to Ar, other rare gases such as Kr, Xe, Ne, and the like, may also be used.

Further, in the processing space 51A, a microwave of the frequency of several GHz, such as the microwave of 2.45 GHz is introduced from the microwave source 112 via the antenna 115, and as a result, there is excited high-density plasma of the plasma density of 10¹¹-10¹²/cm³ on the surface of the substrate W to be processed.

This plasma is characterized by low electron temperature of 0.5-2 eV, and as a result, a processing free from plasma damages is applied to the substrate W to be processed with the plasma processing apparatus 50. Further, because the radicals formed with plasma excitation are removed promptly from the processing space 51A by flowing along the surface of the substrate W to be processed, mutual recombination of the radicals is suppressed, and it is possible to perform a highly uniform and efficient substrate processing at the temperature of 500° C. or less, for example.

Thus, in the step of FIG. 2C, such plasma of low electron temperature is formed in the processing space 51A, and when a hydrogen gas is introduced into such plasma of low electron temperature, the hydrogen gas experiences plasma excitation, resulting in formation of hydrogen radicals H*. The hydrogen radicals H* thus formed easily pass through the densification layer 43 by diffusion and reaches the SiOCH layer 42 underneath, wherein the hydrogen radicals H* thus reached cause therein substitution of the CHx groups such as CH₃ and C₂H₅ or OH group. The substituted CHx groups or OH group is discharged through the densification layer 43 in the form of gas. However, the CHx groups or OH group cannot pass so freely through the densification layer 43 as in the case of the hydrogen radicals, and thus, these species are released with mush slower rate than the conduction rate of hydrogen radicals. Thus, it is preferable to increase the exhaust velocity by way of heating.

As a result, in the step of FIG. 2C, the free CHx groups or OH group forms an internal pressure inside the SiOCH film 42, and thus, there occurs no shrinkage of the film such as substantial increase of density in the film 42, even when such groups are released gradually to the outside of the film through the densification layer 43. Thus, the atomic site (site) of the SiOCH film 42 in which the CHx groups or OH group has caused decoupling and substituted with hydrogen forms a pore, and the main part of the SiOCH film 42 located underneath the densification film 43 changes to the porous film 42A. Thus, the step of FIG. 2C is the pore forming process for forming the pores in the SiOCH film.

In one example, the process of FIG. 2C is carried out at the substrate temperature of 400° C. under the pressure of 267 Pa while supplying the hydrogen gas and the Ar gas respectively with the flow rates of 200 SCCM and 1000 SCCM and supplying the microwave of the frequency of 2.45 GHz to the microwave antenna 55 with the power of 3 kW for 60 seconds. Here, it should be noted that the substrate temperature is set, in the process of FIG. 2C, to be higher than the substrate temperature used in the process of FIGS. 2A and 2B but not exceeding 400° C. When the substrate temperate is set to 400° C. or higher in FIG. 2C, there may arise a problem, in the fabrication of large scale semiconductor integrated circuit devices, that the distribution profile of impurity elements may be changed in the ultra miniaturized transistors already formed on the substrate in the previous processes as a result of the heat used at the time of the substrate processing. Further, it is preferable that the process of FIG. 2C is carried out under the processing pressure of 20-1333 Pa, particularly in the rage of 20-650 Pa. Thereby, it is preferable to use the plasma power of 500 W-6 kW, particularly in the range of 500 W-3 kW. Alternatively, it is preferable to carry out the process under the high pressure of 133.3-1333 Pa and low plasma energy condition.

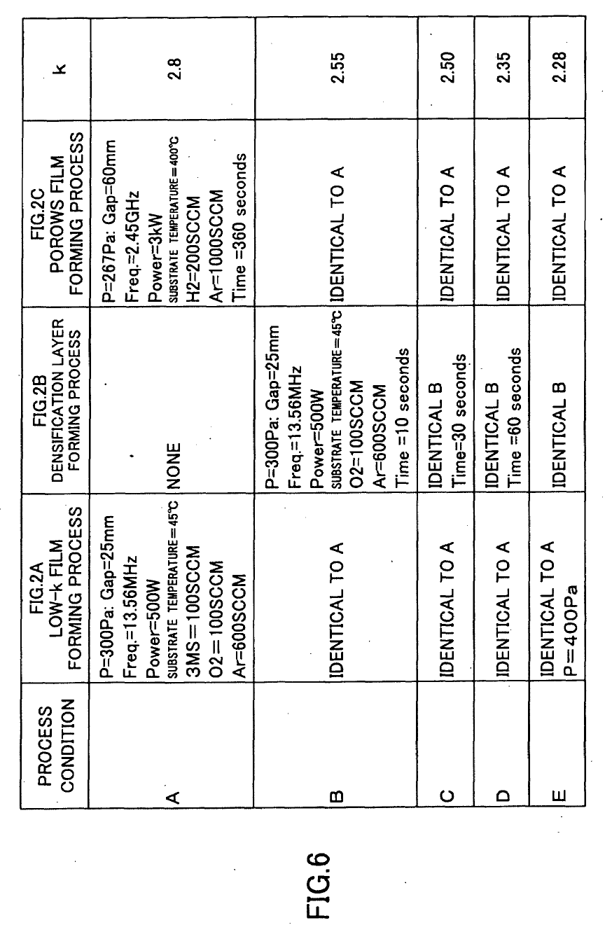

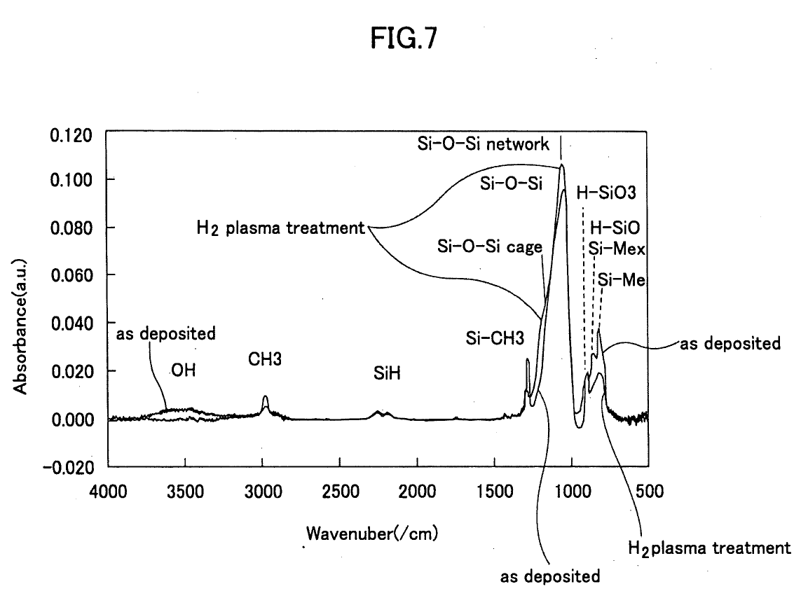

In FIG. 5, it should be noted that data A-D correspond to the experiments conducted under the conditions shown in FIG. 6.

Referring to FIG. 5, it can be seen that, in the case the oxidation processing of FIG. 2B is omitted and the pore forming process of FIG. 2C is carried out directly after the SiOCH film forming process of FIG. 2A, the obtained specific dielectric constant becomes about 2.8 (process condition A), indicating that there is caused shrinkage in the SiOCH film 42 with prompt removal of the CHx groups and the OH group at the time of the hydrogen plasma processing of FIG. 2C, resulting in unsatisfactory pore formation and unsatisfactory decrease of the specific dielectric constant.

Contrary to this, in the case the oxidation processing of FIG. 2B is conducted for 10-60 seconds, the value of the specific dielectric constant decreases with oxidation processing time, resulting in decrease of the specific dielectric constant to 2.55 under the process condition B, 2.52 under the process condition C and 2.4 under the process condition D, provided that the oxidation processing is carried out for 60 seconds. It should be noted that this specific dielectric constant is for the state that includes the densification layer 43, and thus, there should be further decrease of the specific dielectric constant in the case the densification layer 43 is removed after the process of FIG. 2C.

Further, it was confirmed, in the experiment conducted under the same condition to the process condition B of FIG. 6 except that the pressure at the time of film formation is set to 400 Pa (process condition E), that the specific dielectric constant of 2.28 is attained in the case the oxygen plasma processing of FIG. 2B is conducted for 10 seconds. Thus, it is possible to control the specific dielectric constant of the obtained SiOCH film by controlling the pressure at the time of film formation of the SiOCH film, the duration of oxygen plasma irradiation after the film formation, and further the duration of the hydrogen plasma irradiation in the pore forming process, and it is thought that further decrease of specific dielectric constant should be possible.

Thus, it is possible to reduce the k-value of the SiOCH film to less than 3.0 by using the pressure of 133.3 Pa or higher at the time of film formation of the SiOCH film 42 and applying the oxygen plasma processing and/or hydrogen plasma processing subsequently. Further, the k-value can be decreased to 2.3 or lower by setting the pressure at the time of the film formation to 400 Pa or higher.

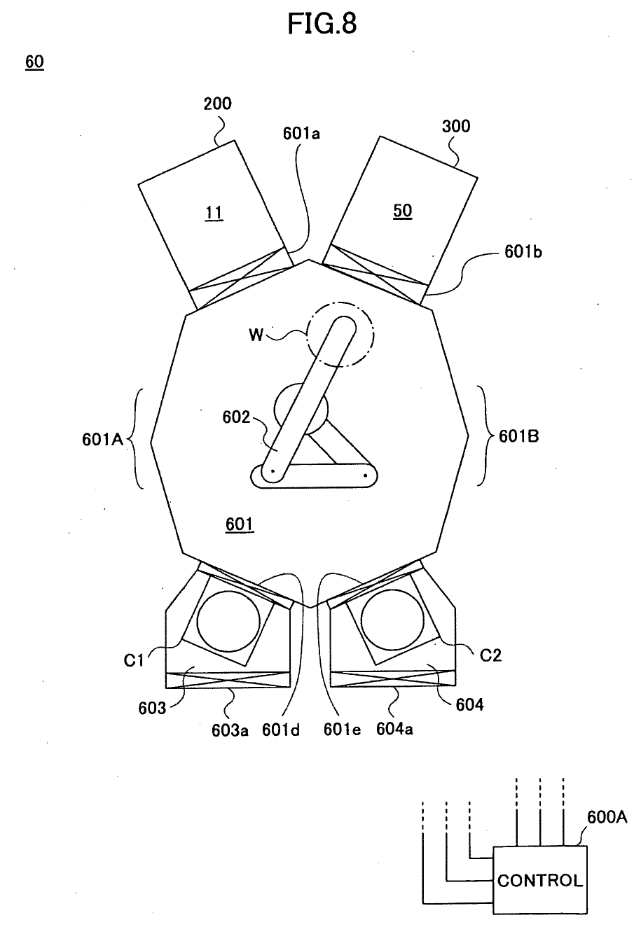

FIG. 7 shows the FT-IR spectrum of the ultra low-K SiOCH film 42A obtained by the densification process and hydrogen plasma processing of FIG. 2C in comparison with the state in which only the film forming process of FIG. 2A is conducted (As-depo). It should be noted that FIG. 7 is for the state in which the densification layer 43 is formed on the SiOCH film 42A. In FIG. 7, identification of the respective absorption peaks is conducted according to Non-Patent Reference 1.

Referring to FIG. 7, it can be seen, from the comparison of the film subjected to the densification processing and the hydrogen plasma processing with the As-depo film, that there is caused decrease of the methyl group or OH group and there is caused increase of absorption at the location corresponding to the Si—O—Si cage structure, while this indicates that there are actually formed pores in the SiOCH film 42A as a result of decoupling of the CHx groups or OH group. Further, in the state of FIG. 2C, it is thought probable, from the increased absorption corresponding to the Si—O—Si network, that there is caused also increase of mechanical strength.

From FIG. 7, it is shown that, as a result of carrying out the porous film formation process of FIG. 2C after the surface densification process of FIG. 2B, that there are actually formed pores in the SiOCH film 42A and the film 42A has been changed to a porous film.

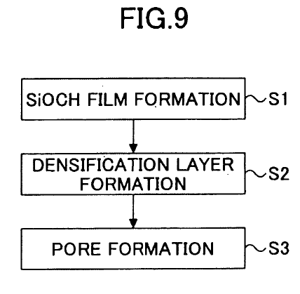

FIG. 8 shows the outline of a clustered substrate processing apparatus 60 used for carrying out the process of FIGS. 2A-2C.

Referring to FIG. 8, the clustered substrate processing apparatus 60 includes a vacuum transfer chamber 601, a movable transfer arm 602 provided in the vacuum transfer chamber 601, a processing chamber 200 coupled to the vacuum transfer chamber 601 and accommodating therein the substrate processing apparatus 11, a processing chamber 300 coupled to the vacuum transfer chamber 601 and accommodating therein the substrate processing apparatus 50 described previously, and load lock chambers 603 and 604 coupled to the vacuum transfer chamber 601.

The processing chambers 200 and 300, the vacuum transfer chamber 601 and the load lock chambers 603 and 604 are connected with evacuation means not illustrated.

Further, the processing chambers 200 and 200, and the load lock chambers 603 and 604 are connected to the vacuum transfer chamber 601 respectively via gate valves 601a-601b, 601d and 601e, which can be opened and closed as desired, and the substrate to be processed is transported from the vacuum transfer chamber to any of the substrate processing chambers or from any of the substrate processing chambers to the vacuum transfer chamber 601 by opening any suitable gate valve noted above.

Further, the load lock chambers 603 and 604 are provided with respective gate valves 603a and 604a, which can be opened and closed as desired, and a wafer cassette C1 accommodating therein a plural number of the substrates to be processed is loaded to the load lock chamber 603 by opening the gate valve 603a. Similarly, a wafer cassette C2 accommodating therein a plural number of the substrates to be processed is loaded to the load lock chamber 604 by opening the gate valve 103b.

In the case of carrying out substrate processing, a substrate Wo to be processed is transported from the cassette C1 or C2 to the processing vessel 200 by the transfer arm 602 via the vacuum transfer chamber 601, while the substrate finished with the processing in the processing chamber 200C is transported to the processing chamber 300 by the transfer arm 102 via the vacuum transfer chamber 601. The substrate W finished with the processing in the processing chamber 300 is then accommodated into the cassette C1 in the load lock chamber 603 or the cassette C2 in the load lock chamber 604.

While the example of two processing chambers are coupled to the vacuum transfer chamber 601 has been shown in FIG. 8, it is also possible to construct a multi chamber system by coupling further processing vessels to the surfaces 601A or 601B of the vacuum transfer apparatus. With this, it becomes possible to carry out the densification processing and hydrogen plasma processing efficiently, and it is possible to form a low-density film with high throughput.

In this case, it is possible to improve the overall throughput of film formation processing by carrying out the film formation and densification processing in the same processing apparatus and carrying out the hydrogen processing in another apparatus, or by carrying out the film forming processing, the densification processing and the hydrogen plasma processing with different processing apparatuses.

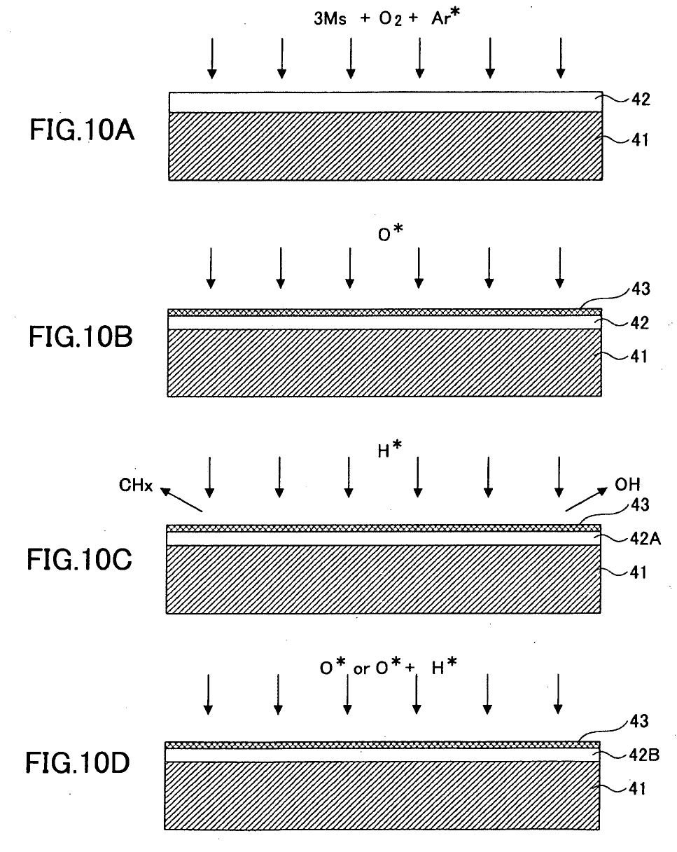

FIG. 9 is a flowchart explaining the overall operation of the clustered substrate processing 60 of FIG. 8.

Referring to FIG. 9, the substrata W to be processed is transported to the processing chamber 200 in the step 1, and deposition of the SiOCH film 42 achieved in the processing vessel 11 by carrying out the process corresponding to FIG. 2A.

Next, while maintaining the plasma in the same substrate processing apparatus 11 and while maintaining the supply of the oxygen gas and the Ar gas, the supply of the organic silane source gas alone is shut down in the step 2, and with this, there occurs formation of the surface densification layer 42 on the surface of the SiOCH film 42 in correspondence to the step of FIG. 2B.

Next, in the step 3, the substrate W to be processed is transported from the processing chamber 200 to the processing chamber 300, and the pore forming process of FIG. 2C is carried out by using substrate processing apparatus 50 of FIGS. 3 and 4.

The substrate processing apparatus 60 of FIG. 8 is provided with a controller 600A for the purpose of controlling such a series of substrate processing process. It should be noted that the forming process of the surface densification layer 42A of the step 2 may also be conducted in the processing chamber 300. In view of the need of elevating the temperature for hydrogen plasma processing after the formation of the surface densification layer 42A of the step 2, it is preferable to carryout the hydrogen plasma processing alone in the different processing chamber 300.

The controller 600A is actually a general purpose computer, wherein the controller 600A reads a recording medium recorded with program code means corresponding to the process of FIG. 7 and controls the respective parts of the substrate processing apparatus 60 according to the foregoing program code means.

In the present embodiment, the film forming process of FIG. 2A is not limited to plasma CVD process but may also be conducted by a coating process.

### Second Embodiment

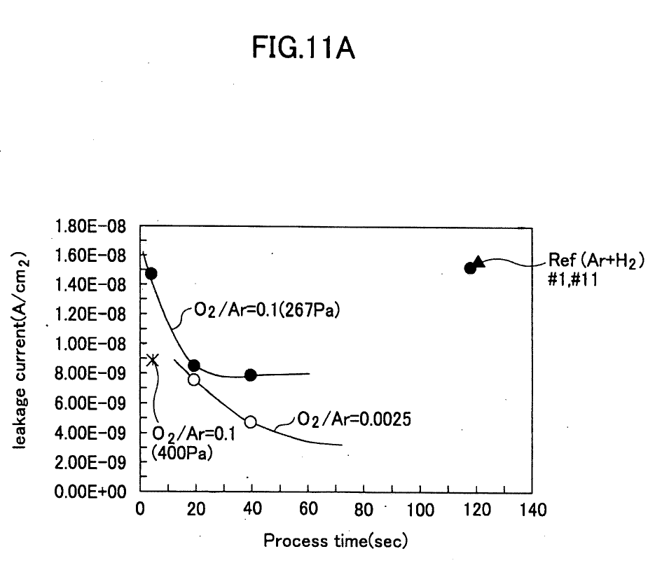

FIGS. 10A-10D show a film forming method according to a second embodiment of the present invention. In the drawings, those parts explained before are designated by the same reference numerals and the description thereof will be omitted.

Referring to FIGS. 10A-10D, it will be noted that the processes of FIGS. 10A-10C are identical to those of FIGS. 2A-2C noted before, while the present embodiment further processes the structure obtained with the process of FIG. 10C with plasma excited oxygen radicals O* or oxygen radicals O* and hydrogen radicals H* in the process of FIG. 10D.

For example, the structure obtained with the process of FIG. 10C is processed in the same microwave plasma processing apparatus at the same substrate temperature (such as 400° C.) while setting the processing pressure to generally the same processing pressure of 20-1333 Pa, preferably 20-650 Pa such as 260 Pa, for example, and by supplying the Ar gas with the flow rate of 250 SCCM and the oxygen gas with the flow rate of 200 SCCM and by supplying the microwave of the frequency of 2.45 GHz with the power of 500 W-2 kW, such as the power of 2 kW. With this, the SiOCH film 42A is modified with the oxygen radicals O* particularly at the surface thereof, and the SiOCH film 42A changes to an SiOCH film 42B. As a result of such a modification process, the damages formed at the surface of the SiOCH film 42A as a result of the oxygen plasma processing of FIG. 10B or the hydrogen plasma processing of FIG. 10C is eliminated or alleviated.

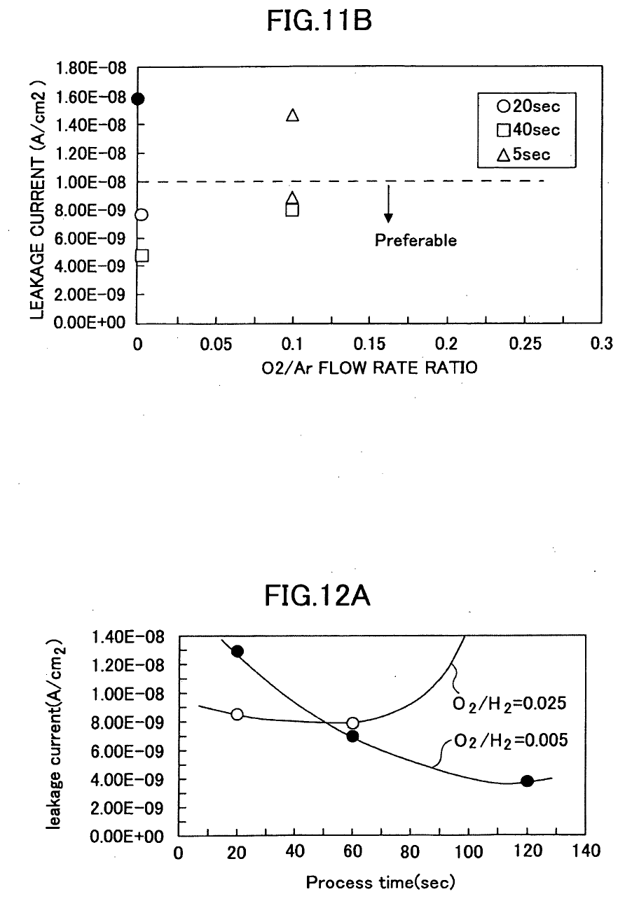

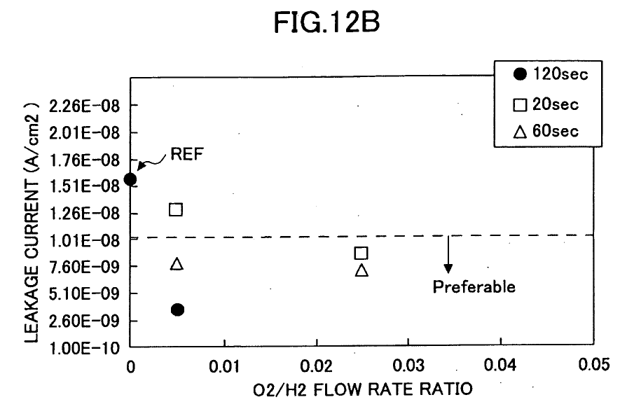

FIGS. 11A and 11B and FIGS. 12A and 12B show the change of the leakage current characteristics of the SiOCH film caused as a result of such a modification processing. It should be noted that FIGS. 11A and 11B show the relationship between the leakage current of the SiOCH film and the duration of modification processing for various oxygen gas/Ar gas flow rate ratios, while FIGS. 12A and 12B show the relationship between the leakage current and the duration of modification processing for various oxygen gas/hydrogen gas flow rate ratios.

In all the experiments of FIGS. 11A and 11B and FIGS. 12A and 12B, a film formed on a p-type silicon substrate by the film forming apparatus 11 of FIG. 1 under the pressure of 100 Pa at the temperature of 25° C. while supplying trimethyl silane with the flow rate of 100 SCCM, oxygen gas with the flow rate of 100 SCCM and Ar gas with the flow rate of 600 SCCM and further supplying the high-frequency power of 27.12 MHz with the power of 250 W, is used for the SiOCH film.

It is preferable that the leakage current of an SiOCH film is suppressed to 1×10⁻⁸ A/cm² or less.

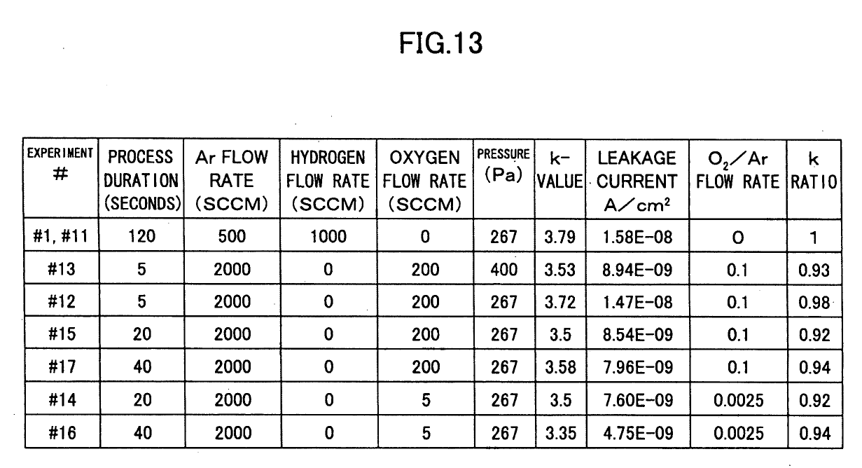

FIG. 13 below shows the details of the experiments in which the modification processing of FIG. 10D is carried out only by oxygen radicals.

Referring to FIG. 13, the experiment #11 applies the hydrogen plasma processing to the SiOCH film obtained with the process of FIG. 10C (hereinafter designated as “initial SiOCH film”) in the substrate processing 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for the duration of 120 seconds.

In the experiment #12, the initial SiOCH film is applied with the hydrogen plasma processing in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for 120 seconds, and subsequently with the oxygen plasma processing, after interrupting all the gases and the microwave power for 55 seconds, under the pressure of 267 Pa at the temperature of 400° C. while supplying the Ar gas with the flow rate of 2000 SCCM and the oxygen gas with the flow rate of 200 SCCM and further supplying the microwave of the frequency of 2.45 GHz with the power of 1.5 kW for 5 seconds.

In the experiment #13, the initial SiOCH film is applied with the hydrogen plasma processing in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for 120 seconds, and subsequently with the oxygen plasma processing, after interrupting all the gases and the microwave power for 55 seconds, under the pressure of 400 Pa at the temperature of 400° C. while supplying the Ar gas with the flow rate of 2000 SCCM and the oxygen gas with the flow rate of 200 SCCM and further supplying the microwave of the frequency of 2.45 GHz with the power of 1.5 kW for 5 seconds.

In the experiment #14, the initial SiOCH film is applied with the hydrogen plasma processing in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for 120 seconds, and subsequently with the oxygen plasma processing, after interrupting all the gases and the microwave power for 55 seconds, under the pressure of 267 Pa at the temperature of 400° C. while supplying the Ar gas with the flow rate of 2000 SCCM and the oxygen gas with the flow rate of 5 SCCM and further supplying the microwave of the frequency of 2.45 GHz with the power of 1.5 kW for 20 seconds.

In the experiment #15, the initial SiOCH film is applied with the hydrogen plasma processing in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for 120 seconds, and subsequently with the oxygen plasma processing, after interrupting all the gases and the microwave power for 55 seconds, under the pressure of 267 Pa at the temperature of 400° C. while supplying the Ar gas with the flow rate of 2000 SCCM and the oxygen gas with the flow rate of 200 SCCM and further supplying the microwave of the frequency of 2.45 GHz with the power of 1.5 kW for 20 seconds.

In the experiment #16, the initial SiOCH film is applied with the hydrogen plasma processing in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for 120 seconds, and subsequently with the oxygen plasma processing, after interrupting all the gases and the microwave power for 55 seconds, under the pressure of 267 Pa at the temperature of 400° C. while supplying the Ar gas with the flow rate of 2000 SCCM and the oxygen gas with the flow rate of 5 SCCM and further supplying the microwave of the frequency of 2.45 GHz with the power of 1.5 kW for 40 seconds.

In the experiment #17, the initial SiOCH film is applied with the hydrogen plasma processing in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and further supplying the microwave of the frequency of 2.45 GHz with the power of 2 kW for 120 seconds, and subsequently with the oxygen plasma processing, after interrupting all the gases and the microwave power for 55 seconds, under the pressure of 267 Pa at the temperature of 400° C. while supplying the Ar gas with the flow rate of 2000 SCCM and the oxygen gas with the flow rate of 200 SCCM and further supplying the microwave of the frequency of 2.45 GHz with the power of 1.5 kW for 40 seconds.

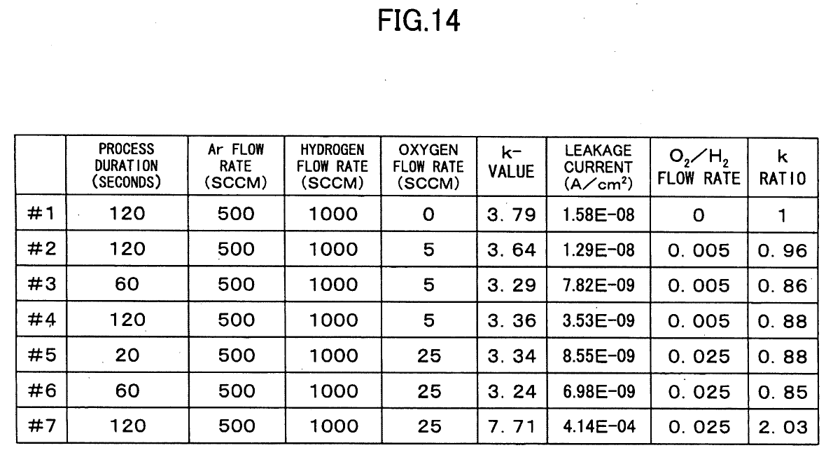

FIG. 14 shows the details of the experiment in which the modification processing of FIG. 10D shown in FIGS. 12A and 12B is carried out by oxygen radicals and hydrogen radicals.

The experiment #1 is identical to the experiment #11 and applies the hydrogen plasma processing to the initial SiOCH film formed with the process of FIG. 10C in the substrate processing 50 of FIG. 3 under the pressure of 267 Pa at the temperature of 400° C. while supplying the Ar gas with the flow rate of 500 SCCM and the hydrogen gas with the flow rate of 1000 SCCM and further irradiating the microwave of the frequency of 2.45 GHz with the power of 2 kW for the duration of 120 seconds.

In the experiment #2, the hydrogen plasma processing is applied to the initial SiOCH film in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and irradiating the microwave of the frequency of 2.45 GHz for the duration of 100 seconds, followed by a hydrogen oxygen plasma processing conducted under the same condition for 20 seconds except that the oxygen gas is added with the flow rate of 5 SCCM and the plasma power is set to 1.5 kW.

In the experiment #3, the hydrogen plasma processing is applied to the initial SiOCH film in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and irradiating the microwave of the frequency of 2.45 GHz with the power of 60 seconds, followed by a hydrogen-oxygen plasma processing conducted under the same condition for 60 seconds except that the oxygen gas is added with the flow rate of 5 SCCM and the plasma power is set to 1.5 kW.

In the experiment #4, the hydrogen plasma processing is applied to the initial SiOCH film in the substrate processing 50 of FIG. 3 under the pressure of 267 Pa at the temperature of 400° C. while supplying the Ar gas with the flow rate of 500 SCCM, the hydrogen gas with the flow rate of 1000 SCCM and the oxygen gas with the flow rate of 5 SCCM and further irradiating the microwave of the frequency of 2.45 GHz with the power of 2 kW for the duration of 120 seconds.

In the experiment #5, the hydrogen plasma processing is applied to the initial SiOCH film in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and irradiating the microwave of the frequency of 2.45 GHz with the power of 2 kW for the duration of 100 seconds, followed by a hydrogen oxygen plasma processing conducted under the same condition for 20 seconds except that the oxygen gas is added with the flow rate of 25 SCCM and the plasma power is set to 1.5 kW.

In the experiment #6, the hydrogen plasma processing is applied to the initial SiOCH film in the substrate processing apparatus 50 of FIG. 3 under the pressure of 267 Pa at the temperature of 400° C. while supplying the Ar gas with the flow rate of 500 SCCM and the hydrogen gas with the flow rate of 1000 SCCM and irradiating the microwave of the frequency of 2.45 GHz with the power of 2 kW for the duration of 60 seconds, followed by a hydrogen oxygen plasma processing conducted under the same condition for 60 seconds except that the oxygen gas is added with the flow rate of 25 SCCM and the plasma power is set to 1.5 kW.

In the experiment #7, the hydrogen plasma processing is applied to the initial SiOCH film in the substrate processing 50 of FIG. 3 under the pressure of 267 Pa at the temperature of 400° C. while supplying the Ar gas with the flow rate of 500 SCCM, the hydrogen gas with the flow rate of 1000 SCCM and the oxygen gas with the flow rate of 25 SCCM and further irradiating the microwave of the frequency of 2.45 GHz with the power of 2 kW for the duration of 120 seconds.

In each of the experiments of FIGS. 13 and 14, the gap length of the plasma processing apparatus 50 is set to 55 mm.

Referring to FIGS. 11A and 11B or FIGS. 12A and 12B, it can be seen that it is possible to improve the leakage current characteristics of the SiOCH film while maintaining the low specific dielectric constant, by applying a post processing of the hydrogen radicals and oxygen radicals or of the oxygen radicals alone, as compared with the case of discontinuing the modification processing in the step of FIG. 10C, and it is possible to attain the leakage current density of 1×10⁻⁸ A/cm² or less.

More specifically, it will be noted that the average specific dielectric constant of 3.79 and the leakage current of 1.58×10⁻⁸ A/cm² are attained in the experiment #1 in which only the hydrogen radical processing is conducted for 120 seconds without oxygen radical processing, while in the experiment #2 in which the processing of the hydrogen radicals and the oxygen radicals is conducted for 20 seconds with the oxygen flow rate of 5 SCCM after the hydrogen radical processing of 100 seconds, the average specific dielectric constant of 3.64 and the leakage current of 1.29×10⁻⁸ A/cm² are attained; in the experiment #3 in which the processing of the hydrogen radicals and the oxygen radicals is conducted for 60 seconds with the oxygen flow rate of 5 SCCM after the hydrogen radical processing of 60 seconds, the average specific dielectric constant of 3.29 and the leakage current of 7.82×10⁻⁹ A/cm² are attained; in the experiment #4 in which the processing of the hydrogen radicals and the oxygen radicals is conducted from the beginning with the oxygen flow rate of 5 SCCM for 120 seconds, the average specific dielectric constant of 3.36 and the leakage current of 3.53×10⁻⁹ A/cm² are attained; in the experiment #5 in which the processing of the hydrogen radicals and the oxygen radicals is conducted for 20 seconds with the oxygen flow rate of 25 SCCM after the hydrogen radical processing of 100 seconds, the average specific dielectric constant of 3.34 and the leakage current of 8.55×10⁻⁹ A/cm² are attained; and in the experiment #6 in which the processing of the hydrogen radicals and the oxygen radicals is conducted for 60 seconds with the oxygen flow rate of 25 SCCM after the hydrogen radical processing of 60 seconds, the average specific dielectric constant of 3.24 and the leakage current of 6.98×10⁻⁹ A/cm² are attained.

Further, with the experiment #11 in which the hydrogen radical processing alone is conducted for 120 seconds without the oxygen radical processing, the average specific dielectric constant of 3.79 and the leakage current of 1.58×10⁻⁸ A/cm² are attained just the same as in the case of the experiment #1, while in the experiment #12 in which the oxygen radical processing is conducted for 5 seconds with the oxygen flow rate of 200 SCCM after the hydrogen radical processing of 120 seconds, the average specific dielectric constant of 3.72 and the leakage current of 1.47×10⁻⁸ A/cm² are attained; in the experiment #13 in which the oxygen radical processing is conducted for 5 seconds with the oxygen flow rate of 200 SCCM under the pressure of 400 Pa after the hydrogen radical processing of 120 seconds, the average specific dielectric constant of 3.53 and the leakage current of 8.94×10⁻⁹ A/cm² are attained; in the experiment #14 in which the oxygen radical processing is conducted for 20 seconds with the oxygen flow rate of 5 SCCM after the hydrogen radical processing of 120 seconds, the average specific dielectric constant of 3.50 and the leakage current of 7.60×10⁻⁹ A/cm² are attained; in the experiment #15 in which the oxygen radical processing is conducted for 20 seconds with the oxygen flow rate of 200 SCCM after the hydrogen radical processing of 120 seconds, the average specific dielectric constant of 3.50 and the leakage current of 8.54×10⁻⁹ A/cm² are attained; in the experiment #16 in which the oxygen radical processing is conducted for 40 seconds with the oxygen flow rate of 5 SCCM after the hydrogen radical processing of 120 seconds, the average specific dielectric constant of 3.35 and the leakage current of 4.75×10⁻⁹ A/cm² are attained; and in the experiment #17 in which the oxygen radical processing is conducted for 40 seconds with the oxygen flow rate of 200 SCCM after the hydrogen radical processing of 120 seconds, the average specific dielectric constant of 3.58 and the leakage current of 7.96×10⁻⁹ A/cm² are attained.

FIGS. 11A and 11B show the relationship between the processing duration and the leakage current based on FIG. 13 for those specimens in which the oxygen gas flow rate to the Ar gas at the time of the oxygen radical processing is set to 0.1 and 0.025. Further, FIGS. 11A and 11B also show the results for the reference specimen (#11) where no oxygen radical processing is made and the specimen in which the pressure at the time of the oxygen radical processing is set to 400 Pa. In FIG. 11A, it should be noted that the horizontal axis represents the processing duration, while in FIG. 11B, the horizontal axis represents the oxygen gas/Ar gas flow rate ratio.

From FIGS. 11A and 11B, it can be seen that the leakage current decreases sharply with the duration of the oxygen radical processing and that the specimen using the oxygen gas/Ar gas flow rate ratio of 0.0025 at the time of the oxygen radical processing provides lower leakage current as compared with the specimen of the oxygen gas/Ar gas flow rate ratio of 0.1.

From the relationship of FIGS. 11A and 11B, it can be seen that it is preferable to carry out such oxygen radical processing for the duration of 10 seconds or more, more preferably 20 seconds or more.

FIGS. 12A and 12B show the relationship between the processing duration and the leakage current based on FIG. 14 for those specimens in which the oxygen gas flow rate to the hydrogen gas at the time of the oxygen radical processing is set to 0.005 and 0.025. Further, FIG. 12B also show the results for the reference specimen (#1) where no oxygen radical processing is conducted. In FIG. 12A, it should be noted that the horizontal axis represents the processing duration, while in FIG. 12B, the horizontal axis represents the oxygen gas/hydrogen gas flow rate ratio.

Referring to FIGS. 12A and 12B, it can be seen that the leakage current decreases with progress of the oxygen radical processing, while when the processing duration exceeds about 60 seconds in the specimen in which the oxygen gas/hydrogen gas flow rate ratio is set to 0.025, it can be seen that the leakage current starts to increase.

On the other hand, in the experiments in which the flow rate ratio of the oxygen gas to the hydrogen gas is 0.005, there can be seen no increase in the k value and the leakage current even when the processing duration is extended further.

From the relationship of FIGS. 12A and 12B, it can be seen that it is preferable to carry out such oxygen radical processing for the duration of 10 seconds or more, more preferably 20 seconds or more.

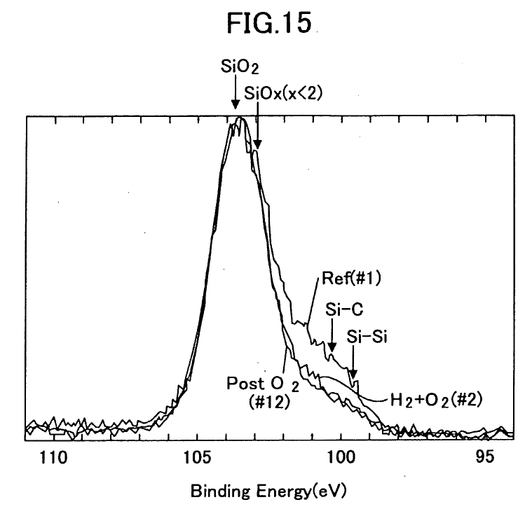

FIG. 15 shows the XPS (X-ray photoelectron spectroscopy) spectrum of the SiOCH film specimen obtained with the experiment #2 of FIG. 13 and the experiment #12 of FIG. 14, in comparison with the XPS spectrum of the SiOCH film specimen obtained with the comparative experiment #1 of FIG. 13, and hence with the experiment #1 of FIG. 14.

Referring to FIG. 15, it can be seen that, with the specimen of the comparative experiment, a peak corresponding to the Si—C bond or Si—Si bond is observed, while it can be seen that, with the post processing of FIG. 10D, these bonds are decreased in the film and substantially disappeared in any of the case in which the post processing is carried out with H* (hydrogen radicals) and O* (oxygen radicals) or with O* alone. This implies that the surface of the SiOCH film is modified to a composition enriched with SiO₂ by O*.

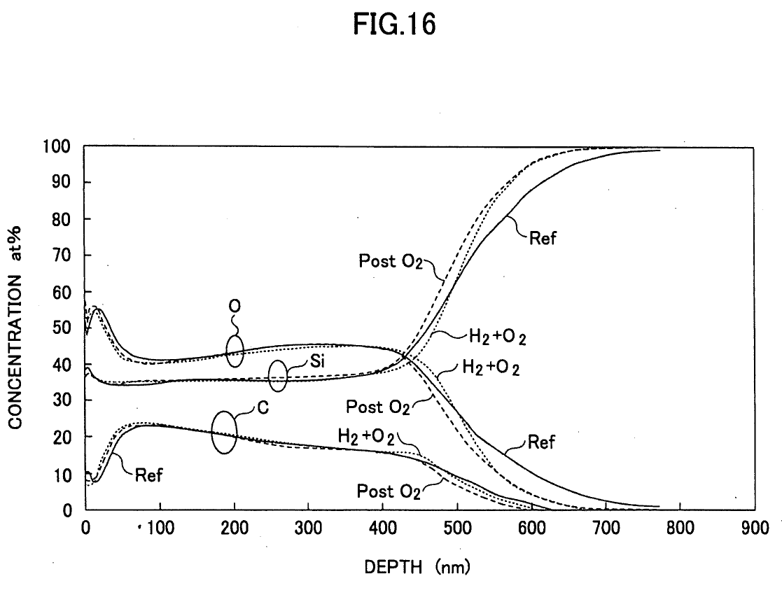

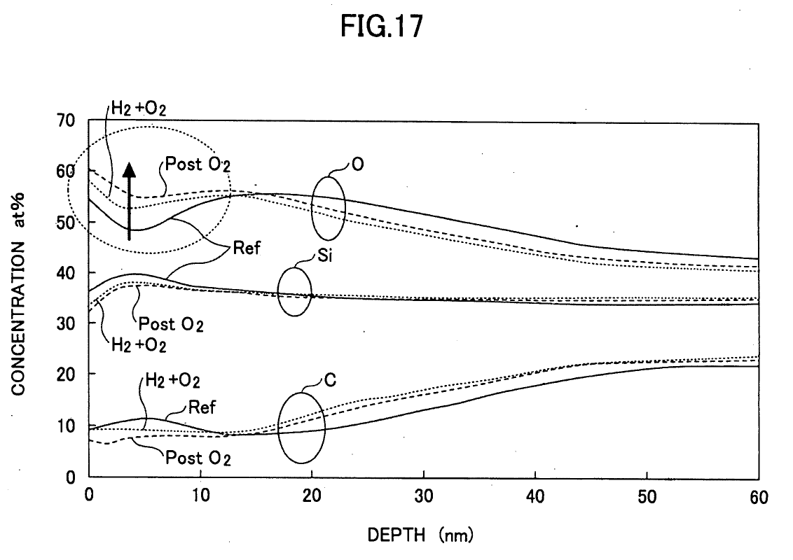

FIGS. 16 and 17 show an XPS depth profile of Si, O and C obtained for the SiOCH film thus formed.

Referring to FIGS. 16 and 17, the data designated as “Ref” represent the specimen in which the processing is discontinued after the steps of FIGS. 10A-10C, the data designated as “Post O2” represent the specimen in which the surface of the SiOCH film is subjected to the oxygen plasma processing in the step of FIG. 10D, while the data designated as “H₂+O₂” represent the specimen in which the surface of the SiOCH film is processed with the oxygen radicals and nitrogen radicals in the step of FIG. 10D.

Particularly, from the enlarged diagram of FIG. 17, it can be seen that there is formed a damaged layer in the surface part of the SiOCH film of the reference specimen (#1 and #11) with the thickness of 20-30 nm as a result of reduction caused by the hydrogen radicals. When such a surface damaged layer is formed, there occurs increase of proportion of the Si—C bond, while this causes the problems such as increase of leakage current or increase of specific dielectric constant. Further, as a result of the hydrogen plasma processing, there is caused decoupling of oxygen in the oxygen-enriched surface densification layer 43 formed on the surface of the SiOCH film 42A. Thus, it is thought that the surface densification layer formed with the process of FIG. 10B has a thickness of about 20-30 nm.

With the present embodiment, on the other hand, such depletion of oxygen in the surface part of the SiOCH film is replenished by carrying out the oxygen plasma processing or hydrogen and oxygen plasma processing as the post processing, resulting in curing of the damages. Thereby, the decrease of the specific dielectric constant and decrease of the leakage current are attained as shown in FIGS. 11A and 11B.

It should be noted that the process of FIG. 10D can be carried out, in the case of using the clustered substrate processing apparatus 60 explained previously with reference to FIG. 8, by carrying out the foregoing processing in continuation in the processing vessel 300.

### Third Embodiment

In the embodiments explained previously, it will be noted that the densification layer 43 remains on the porous SiOCH film 42A. Thereby, it is preferable to remove the densification layer 43 because such densification layer 43 functions to increase the overall specific dielectric constant of the SiOCH film.

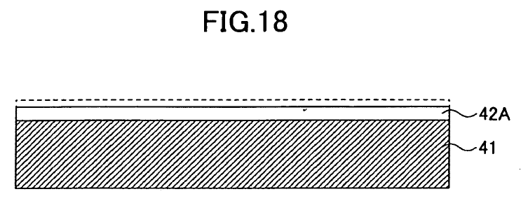

Thus, the present embodiment removes the densification layer 43 in a densification layer removal process of FIG. 18 conducted subsequent to the step of FIG. 2C, by way of Ar sputtering process or CMP process.

For example, it is possible to remove the densification layer 43 by carrying out the process of FIG. 18 in a plasma processing apparatus 400 at the substrate temperature of 280° C. while supplying an Ar gas with the flow rate of 5 SCCM and supplying a high frequency wave of 13.56 MHz to a high frequency coil thereof with a power of 300 W and further supplying a high frequency bias of the frequency of 2 MHz to the substrate to be processed with a power of 300 W and carrying out a sputter etching process for 130 seconds. As a result, the surface densification layer is removed, and it becomes possible to decrease the specific dielectric constant of about 2.2 to 2.0. Thereby, it becomes possible to form a ultra low-dielectric constant film.

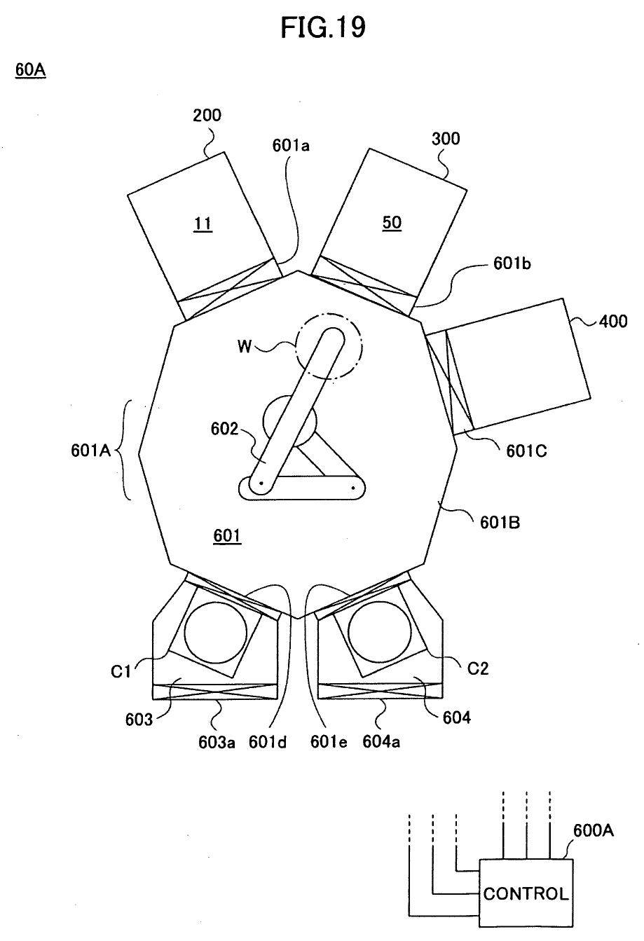

FIG. 19 shows the construction of a clustered substrate processing apparatus 60A carrying out the film forming process of the present embodiment including the process of FIG. 18. In FIG. 19, those parts explained before are designated by the same reference numerals and the description thereof will be omitted.

Referring to FIG. 19, the substrate processing apparatus 60A includes a processing chamber 400 coupled to the vacuum transfer chamber 601 via a gate valve 601c wherein, in the illustrated example, the processing chamber 400 is provided with an ICP plasma processing apparatus. Further, it is also possible to provide a microwave plasma processing apparatus to the processing chamber 400.

Thus, the substrate finished with processing for the process of FIG. 2C or FIG. 10D in the processing chamber 300 is transported to the processing chamber 400 via the vacuum processing chamber 601 via the transfer mechanism 602, and the removal of the surface densification layer of FIG. 18 is carried out by a sputtering process.

Further, it is also possible in the processing chamber 300 to take out the substrate finished with the process of FIG. 2C or FIG. 10D via the load lock chamber 603 or 604 and carry out the process of FIG. 18 in a separate CMP apparatus.

### Fourth Embodiment

With the process of FIG. 2B or FIG. 10B explained previously, the process of forming the desired surface densification layer is carried out, after formation of the SiOCH film 42 with the step of FIG. 2A or FIG. 10A, by continuously supplying the Ar gas and the oxygen gas and the high-frequency power while interrupting the supply of the organic silane gas alone.

The inventor of the present invention has discovered that, in the experiment of FIGS. 2A-2C noted before, that there are cases in which large a number of particles are formed on the surface of the substrate to be processed particularly in the finishing process of the SiOCH film forming process of FIG. 2A.

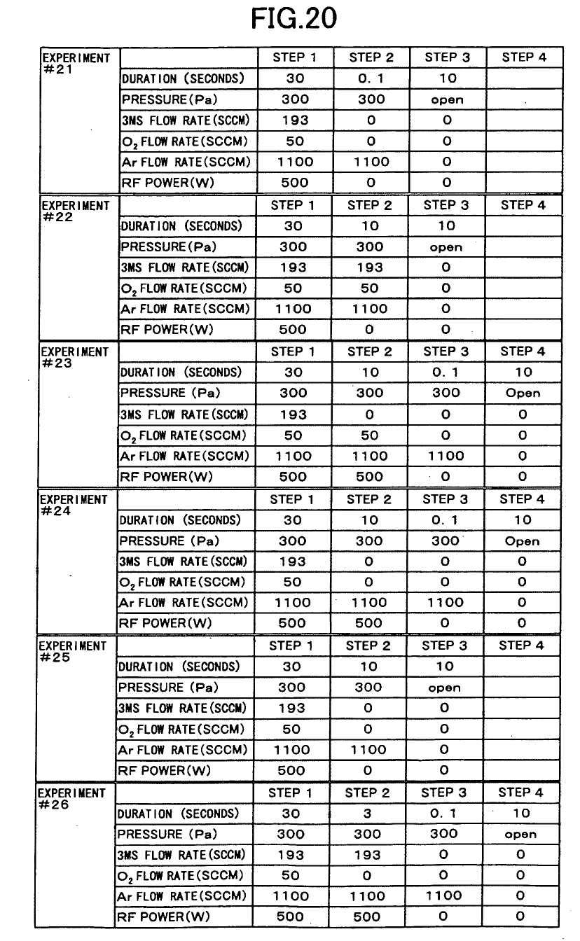

FIG. 20 shows the experiment carried out by the inventor of the present invention.

Referring to FIG. 20, film formation of the SiOCH film 42 is carried out in the step 1 and finishing process of film formation is carried out in the steps of 2-4. Here, the film formation of the SiOCH film 42 is carried out at the substrate temperature of 45° C.

In the experiment #21, supply of the trimethyl silane source gas and the oxygen gas is interrupted simultaneously to the interruption of the high-frequency power, and the Ar gas is caused to flow for 0.1 seconds in the step 2. Further, the processing is terminated in the step 3. In this experiment #21, it was confirmed by SEM observation that there are formed particles of the diameter of 0.1 μm or larger on the surface of the substrate thus processed with a density of 1×10⁸ particles/cm².

In the experiment #22, the supply of the trimethyl silane source gas, the oxygen gas and the Ar gas is continued in the step 1 and only the high-frequency power is shut down. Further, in the step 2, supply of the trimethyl silane source gas, the oxygen gas and the Ar gas is shut down. With this experiment #22, it was confirmed by SEM observation that there are formed particles of the diameter of 0.13 μm or larger on the surface of the substrate thus processed with a density of 5×10⁷ particles/cm².

In the experiment #23, the trimethyl silane source gas alone is stopped in the step 2 while continuing the supply of the oxygen gas and the Ar gas and further continuing the high-frequency power, and the supply of the oxygen gas and the high-frequency power is shut down in the step 3 after 0.1 seconds while continuing the supply of the Ar gas. Further, in the step 4, the supply of the Ar gas is stopped after 10 seconds. With this experiment #23, it was confirmed by the measurement with particle counter that there are formed particles of the diameter of 0.13 μm or larger on the surface of the substrate thus processed with a density of 0.06 particles/cm².

In the experiment #24, the supply of the trimethyl silane source and the oxygen gas is shut down in the step 2 while continuing the supply of the high-frequency power, and the supply of the high-frequency power is shut down in the step 3 after 0.1 seconds while continuing the supply of the Ar gas. Further, in the step 4, the supply of the Ar gas is stopped after 10 seconds. With this experiment #24, it was confirmed by SEM observation that there are formed particles of the diameter of 0.1 μm or larger on the surface of the substrate thus processed with a density of 2×10⁷ particles/cm².

In the experiment #25, the supply of the trimethyl silane source gas, the oxygen gas and the high-frequency power is stopped in the step 2 while continuing the supply of the Ar gas, and the supply of the Ar gas is stopped in the step 3 after 10 seconds. With this experiment #25, it was confirmed by SEM observation that there are formed particles of the diameter of 0.13 μm or larger on the surface of the substrate thus processed with a density of 2×10⁷ particles/cm².

In the experiment #26, the supply of the oxygen gas alone is stopped in the step 2 while continuing the supply of the trimethyl silane gas, the Ar gas and the high-frequency power, and the supply of the trimethyl silane gas and the high-frequency power is stopped in the step 3 after 0.1 seconds while continuing the supply of the Ar gas. Further, in the step 4, the supply of the Ar gas is stopped after 10 seconds. With this experiment #26, it was confirmed by SEM observation that there are formed particles of the diameter of 0.13 μm or larger on the surface of the substrate thus processed with a density of 5×10⁷ particles/cm².

From the results explained above, it can be seen that it is effective to suppress the particle formation, in the case of forming the SiOCH film by a plasma CVD process in a parallel-plate type substrate processing apparatus, to stop the supply of the trimethyl silane source gas in advance and stop the supply of the oxygen gas and the high-frequency power thereafter as in the experiment #23.

Such a finishing sequence of film forming processing is equivalent of carrying out the densification processing of FIG. 2B conducted after the film forming processing of FIG. 2A, and thus, it is understood that, with the process of FIGS. 2A-2C or FIGS. 10A-10C, particle formation associated with finishing of film formation of the SiOCH film is minimized as a result.

Further, the inventor of the present invention has made a search of optimum post processing condition capable of suppressing particle formation while using the parallel-plate type substrate processing apparatus 11 of FIG. 1.

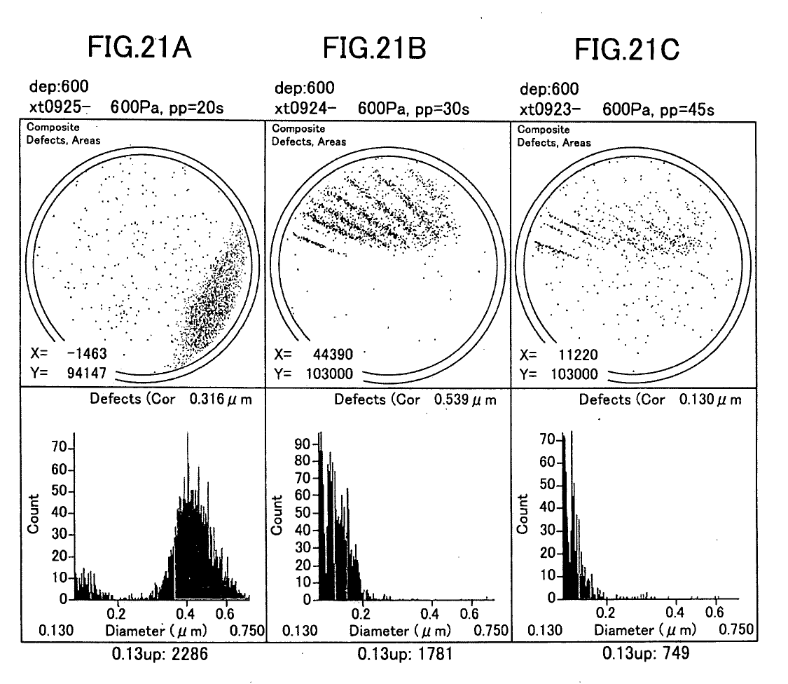

FIGS. 21A-21C show the mode of particle formation for the case of carrying out the processing of FIGS. 2A and 2B under the processing pressure of 600 Pa, in which particle formation is most probable, while changing the duration of the oxygen plasma processing of FIG. 2B variously. In FIGS. 21A-21C, it should be noted that the gap of the substrate processing apparatus 11 is set to 25 mm and the substrate temperature is set to 45° C., wherein the film formation process of the SiOCH film is carried out in the step of FIG. 2A while setting the flow rates of the trimethyl silane gas, the oxygen gas and the Ar gas respectively to 100 SCCM, 100 SCCM and 600 SCCM and supplying the high-frequency wave of 13.56 MHz for 6.8 seconds. In the step of FIG. 2B, the oxygen plasma processing is carried out under the same condition for the duration of 20-45 seconds while stopping the trimethyl silane gas alone. In FIGS. 21A-21C, it should be noted that the upper diagram show the in-plane distribution of the particles on the substrate surface, while the lower diagram shows the diameter distribution of the particles thus formed.

FIG. 21A shows the case in which the duration of the oxygen plasma processing of FIG. 2B is set to 20 seconds. It can be seen that there are formed a large number of particles of the diameter of 0.4 μm or larger.

Contrary to this, FIG. 21B shows the case of setting the oxygen plasma processing of FIG. 2B for 30 seconds. There, it can be seen that formation of the particles of the diameter of about 0.4 μm or larger is suppressed and that most of the particles have a diameter of 0.2 μm or less. Similar tendency is observed also in FIG. 21C in which the duration of the oxygen plasma processing is set to 45 seconds.

Thus, according to the results of FIGS. 21A-21C, the oxygen plasma processing of FIG. 2B conducted for the duration of 30 seconds or more is effective for suppressing the particle formation at the time of finishing the film formation process, while this approach is not effective for suppressing the particle formation for the particles of the diameter of 0.13 μm or less. With regard to the particles of this range of particle diameter, it can be seen that there is caused increase in the number of the particles.

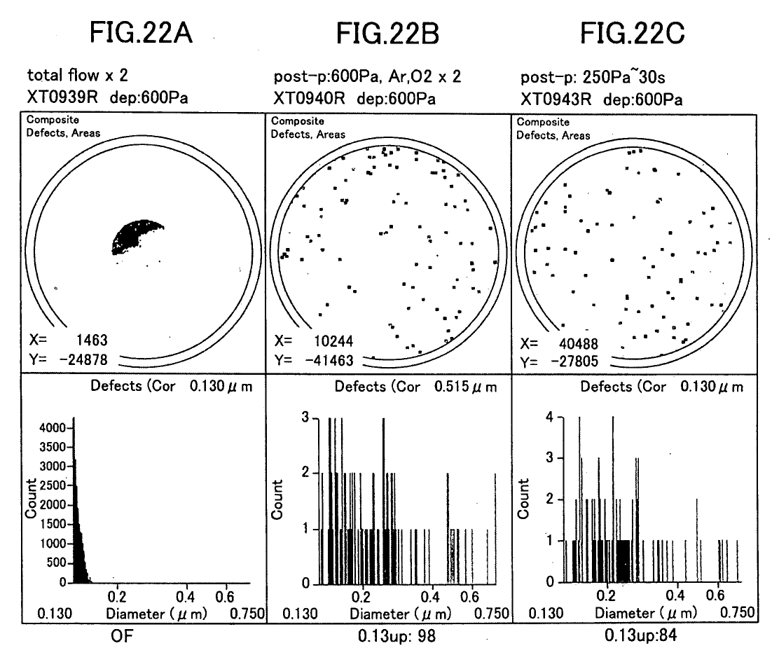

Contrary to this, FIG. 22A shows the situation of the particle formation for the case the flow rates of the trimethyl silane gas the oxygen gas and the Ar gas are increased by twice in the step of FIG. 2B subsequently to the step of FIG. 2A while maintaining the same substrate temperature, processing pressure and plasma power.

Referring to FIG. 22A, it can be seen that the situation is slightly improved as compared with the case of FIG. 21C but there are still caused extensive formation of the particles of the grain diameter of 0.1 μm.

Further, FIG. 22B shows the situation of particle formation in the event the oxygen plasma processing is conducted, after the film forming process of the SiOCH film of FIG. 2A under the same condition to the case of FIG. 21A explained before, for the duration of 30 seconds while using the same process condition, except that the flow rates of the oxygen gas and the Ar gas are increased twice.

Referring to FIG. 22B, it can be seen that, with such increase of flow rate of the Ar gas and oxygen gas in the oxygen plasma processing conducted subsequently to the film forming process, it becomes possible to decrease the particle formation drastically.

Further, FIG. 22C shows the situation of particle formation in the event the oxygen plasma processing is conducted, after the film forming process of the SiOCH film of FIG. 2A under the same condition to the case of FIG. 21A explained before, for the duration of 30 seconds while using the same process condition, except that the processing pressure is decreased to 250 Pa.

Referring to FIG. 22C, it can be seen that there is also caused drastic decrease in the particle formation after the film forming process.

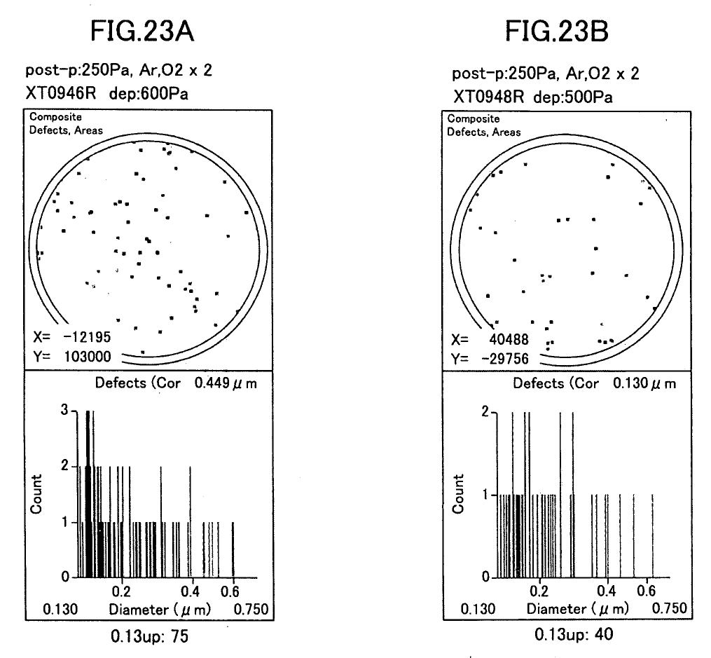

FIG. 23A shows the situation of particle formation for the case in which the oxygen plasma processing of FIG. 2B is conducted under the pressure of 250 Pa, which is lower than the process pressure used for the film formation process of FIG. 2A, while increasing the flow rates of the oxygen gas and the Ar gas twice as compared with the case of the film forming process of FIG. 2A.

Referring to FIG. 23A, it can be seen that the particle formation is suppressed further as compared with any of the cases of FIGS. 22B and 22C.

Further, FIG. 23B shows the situation of particle formation for the case the processing pressure at the time of film of film formation of FIG. 2A is set to 500 Pa and the finishing process of film formation similar to the case of FIG. 23A is carried out in correspondence to the process of FIG. 2B.

Referring to FIG. 23B, it can be seen that the particle formation is suppressed further.

Thus, it is possible to suppress the particle formation further efficiently, by carrying out the oxygen plasma processing of FIG. 2B or FIG. 10B explained previously under the pressure lower than that used in the film forming process of FIG. 2A or FIG. 10A and further under the condition in which the oxygen gas flow rate and the Ar gas flow rate are increased.

Further, it should be noted that such oxygen plasma processing conducted at the time of the finishing process of the film formation process is effective not only in the case of forming the SiOCH film in the parallel-plate type substrate processing apparatus shown in FIG. 1 but also in the case of conducting the film forming process of an SiCO film in the microwave plasma processing apparatus shown in FIGS. 3 and 4 while supplying trimethyl silane gas, Ar gas and oxygen gas.

Further, while explanation has been made heretofore for the case of using trimethyl silane (TMS: SiH(CH₃)₃) for the organic silicon compound source, it should be noted that the organic silicon compound source of the present invention is not limited to trimethyl silane and it is also possible to use dimethyl silane (SiH₂(CH₃)₂), tetramethyl silane (Si(CH₃)₄), dimethyldimethoxy silane (DMDMOS: Si(CH₃)₂(OCH₃)₂), dimethyldiethoxy silane (Si(CH₃)₂(OC₂H₅)₂), dimethylethoxy silane (Si(CH₃)₂(OC₂H₅)), methoxytrimethyl silane (Si(CH₃)₃(OC₂H₅)), methyltriethoxy silane (Si(CH₃)(OC₂H₅)₃), diethylmethyl silane (Si(C₂H₅)₂(CH₃)), ethyltrimethyl silane (Si(C₂H₅)₂(CH₃)₃), ethoxytrimethyl silane (Si(CH₃)₃(OC₂H₅)), diethoxymethyl silane (DEMS: SiH(OC₂H₅)₂ (CH₃)), ethyltrimethoxy silane (Si(C₂H₅)(OCH₃)₃), and the like.

While the present invention has been explained for preferred embodiments, the present invention is not limited to such specific embodiments and various variations and modifications may be made within the scope of the invention described in patent claims.

The present invention based on Japanese priority application 2006-005928 filed on Jan. 13, 2006, the entire contents of which are incorporated herein as reference.

### INDUSTRIAL APPLICABILITY

According to the present invention, the organic functional groups generally designated as CHx, such as CH₃, C₂H₅, . . . , or the hydroxyl group (OH) contained in the dielectric film is discharged to the outside of the film with a controlled rate in the pore forming step, by carrying out the film formation of the porous film by the steps of: forming the dielectric film containing an organic functional group and a hydroxyl group on a substrate by an organic silicon compound source; forming a surface densification layer having a higher density than a main part of the dielectric film on a surface of the dielectric film by carrying out a densification processing removing the organic functional group and the hydroxyl group; and forming pores in the main part of the dielectric film by exposing the dielectric film formed with the surface densification layer to the hydrogen radicals excited by plasma such that the organic functional group and the hydroxyl group are removed. Thereby, it becomes possible to suppress the shrinkage of the dielectric film at the time of the pore forming step effectively. As a result, increase of density of the dielectric film is suppressed and it becomes possible to obtain a dielectric film of low dielectric constant.

Further, by stopping the supply of the film forming source gas alone, after the film forming process, while continuing the supply of the plasma gas and the oxidizing gas and further continuing the supply of the plasma power, formation of particles at the end of the film forming process is effectively suppressed, and it becomes possible to improve the yield of film formation significantly.

What is claimed is:

1. A film forming method of a porous film, comprising the steps of:
forming a dielectric film containing an organic functional group and a hydroxyl group on a substrate by using an organic silicon compound source;
forming a densification layer on a surface of said dielectric film by applying a densification processing to said surface of said dielectric film, said densification processing removing said organic functional group;
exposing said dielectric film to hydrogen radicals excited by plasma; and
forming pores in a main part of said dielectric film by exposing said dielectric film to hydrogen radicals excited by plasma such that said organic functional group and hydroxyl group are removed.

2. The film forming method as claimed in claim 1, wherein said step of forming pores is conducted by exposing said dielectric film formed with said densification layer to said hydrogen radicals.

3. The film forming method as claimed in claim 1, wherein said step of forming said dielectric film is conducted by a plasma CVD process at a first temperature in the range from room temperature to 200° C., said step of forming said surface densification layer is conducted by a plasma processing at a second temperature in the range from room temperature to 200° C., and wherein said step of forming pores is conducted at a third temperature higher than any of said first and second temperatures.

4. The film forming method as claimed in claim 3, wherein said first and second temperatures are about 45° C. and wherein said third temperature is about 400° C.

5. The film forming method as claimed in claim 1, wherein said step of forming said dielectric film and said step of applying said densification processing are conducted in an identical substrate processing apparatus and wherein said step of forming pores is conducted in another substrate processing apparatus.

6. The film forming method as claimed in claim 1, wherein said step of forming said dielectric film is conducted by supplying a source gas of said organic silicon compound source to said substrate surface together with an oxidizing gas and an inert gas, and wherein said step of forming said surface densification layer is conducted, subsequently to said step of forming said dielectric film, by interrupting supply of said source gas alone while maintaining plasma and wile continuing supply of said oxidizing gas and inert gas.

7. The film forming method as claimed in claim 6, wherein said step of forming said surface densification layer is finished by stopping said plasma and supply of said oxidizing gas while continuing supply of said inert gas.

8. The film forming method as claimed in claim 6, wherein said step of forming said surface densification layer is conducted by increasing a flow rate of said oxidizing gas and inert gas as compared with said step of forming said dielectric film.

9. The film forming method as claimed in claim 1, wherein said step of forming said surface densification layer is conducted under a processing pressure lower than in said step of forming said dielectric film.

10. The film forming method as claimed in claim 1, wherein said dielectric film is an SiOCH film, and wherein said densification processing comprises a step of processing said surface of said dielectric film formed on said substrate with oxygen radicals excited by plasma, such that said surface densification layer contains oxygen with a concentration higher than said main part of said dielectric film and such that said surface densification layer contains carbon with a concentration lower than said main part of said dielectric film.

11. The film forming method as claimed in claim 1, wherein said step of densification processing forms said surface densification layer with a thickness not exceeding 30 nm.

12. The film forming method as claimed in claim 1, wherein said step of densification processing is conducted such that there is formed an Si—O—Si cage structure in a main part of said dielectric film.

13. The film forming method as claimed in claim 3, wherein said step of forming said dielectric film and said step of applying densification processing are carried out in a parallel-plate type plasma CVD apparatus under a pressure of 100-1000 Pa while supplying a plasma power of 100-750 W, and where in said step of forming pores is conducted in a microwave plasma processing apparatus under a pressure of 100-1000 Pa while supplying a plasma power of 100-750 W.

14. The film forming method as claimed in claim 1, further comprising a step of applying a post processing to said dielectric film having said surface densification layer with an oxidizing ambient.

15. The film forming method as claimed in claim 14, wherein said step of applying post processing is conducted by oxygen radicals excited with plasma.

16. The film forming method as claimed in claim 15, wherein hydrogen radicals excited with plasma is added in said step of applying post processing.

17. The film forming method as claimed in claim 14, wherein said step of applying post processing is conducted in continuation to said step of forming pores in an identical plasma processing apparatus.

18. The film forming method as claimed in claim 1, further comprising, after said step of forming pores, of a step of removing said surface densification layer.

19. The film forming method as claimed in claim 18, wherein said removing step of said surface densification layer is conducted after said step of applying post processing.

20. The film forming method as claimed in claim 18, wherein said removing step comprises a sputtering process conducted by plasma containing a rare gas.

21. The film forming method as claimed in claim 19, wherein said removing step is conducted by a chemical mechanical polishing process.
